(19) United States
(12) Patent Application Publication
(10) Pub. No.: US 2023/0207525 A1
(43) Pub. Date: Jun. 29, 2023

(54) IC DIE STACKING WITH MIXED HYBRID AND SOLDER BONDING

(71) Applicant: Intel Corporation, Santa Clara, CA (US)

(72) Inventors: Debendra Mallik, Chandler, AZ (US); Sriram Srinivasan, Chandler, AZ (US); Christopher Pelto, Beaverton, OR (US); Gwang-Soo Kim, Portland, OR (US); Nitin Deshpande, Chandler, AZ (US); Omkar Karhade, Chandler, AZ (US)

(73) Assignee: Intel Corporation, Santa Clara, CA (US)

(21) Appl. No.: 17/561,845

(22) Filed: Dec. 24, 2021

(51) Int. Cl. H01L 25/065; H01L 23/00; H01L 23/31

(52) U.S. Cl. CPC H01L 25/0657; H01L 23/3185; H01L 24/08; H01L 24/16; H01L 24/73; H01L 2224/08145; H01L 2224/16145; H01L 2224/73253; H01L 2225/06568

(57) ABSTRACT

A packaged device comprises first die stack and a third die. The first die stack includes a first die comprising first conductive contacts each at a first side of the first die, and a second die comprising second conductive contacts each at a second side of the second die. First solder bonds which each extend to a respective one of the first conductive contacts. The third die comprises third conductive contacts each at a third side of the third die. The third die is coupled to the first die stack via second solder bonds which each extend to a respective one of the second conductive contacts, and to a respective one of the third conductive contacts. Each die of the first die stack is coupled to each of a respective one or more other dies of the first die stack via respective hybrid bonds.

### BACKGROUND

Monolithic integrated circuit (IC) fabrication has restrictions that may limit a final product’s performance. For this reason, alternatives to monolithic fabrication, such as various versions of IC die (dis)integration, are being investigated. One alternative to monolithic IC fabrication is assembling multiple chips into a multi-chip package (MCP). Another alternative is wafer-level stacking. With the wafer-level stacking technique, two or more wafers of monolithically fabricated ICs are bonded together. The wafers are then singulated into multiple stacked chip packages. Yet another alternative is die stacking. In die stacking, singulated IC die are vertically stacked after all the metallization layers in the separate IC dies have been completed.

An advantage of multi-chip packages is that they may enable IC dies from heterogeneous silicon processes to be combined, enable small dis-aggregated IC dies from identical silicon processes to be combined, or both. However, there are many challenges with integrating multiple IC dies into a single IC package.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a cross-sectional view of a packaged device comprising a base die, a first die stack, and a second die stack, according to some embodiments.

FIG. 2 is a cross-sectional, exploded view of the packaged device of FIG. 1, according to some embodiments.

FIG. 3 is a cross-sectional of a packaged device illustrating a base die, a first die stack, and a second die stack, according to some embodiments.

FIG. 4 is a cross-sectional view of a packaged device illustrating a base die, a first die stack, and a second die stack, according to some embodiments.

FIG. 5 is a cross-sectional view of a packaged device illustrating a base die, a first die stack, and a monolithic die, according to some embodiments.

FIG. 6 is a cross-sectional view of a packaged device illustrating a base die, a lower die stack, and an upper die stack, according to some embodiments.

FIG. 7 is a cross-sectional view of a packaged device illustrating a base die, a lower die stack, and an upper die stack, according to some embodiments.

FIG. 8 is a cross-sectional view of a packaged device comprising a base die, a first die stack, a second die stack, and underfill, according to some embodiments.

FIG. 9 illustrates a flow diagram of methods for assembling a packaged device according to some embodiments.

FIG. 10 illustrates a mobile computing platform and a data server machine employing a packaged device having a first die stack and a third die coupled to the first die stack via solder bonding, in accordance with some embodiments.

FIG. 11 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning. In addition, the term “conductive contact” may be used for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The IC package examples described herein may be manufactured, in part, with bonding techniques in which metal features embedded within an insulator of one IC die are directly fused to metal features embedded within an insulator of another die. Where both the metal features and the insulators are fused, the resultant composite structure comprises a hybrid bonded interface of both metallurgically interdiffused metals and chemically bonded insulators. Prior to bonding, each IC die may be fabricated in a monolithic process separate from that of the other IC die. As such, an IC die may utilize the same or different semiconductor device fabrication technologies as the IC die to which it is bonded.

According to various embodiments, a packaged device includes a first die stack having a first die and a second die coupled to each other via hybrid bonding, and a third die coupled to the first die stack via solder bonding. More specifically, some embodiments are directed to a first die stack and a third die. The first die stack has the first die and the second die. The first die has first conductive contacts. Each of the first conductive contacts are at a first side of the first die. The second die has second conductive contacts. Each of the second conductive contacts are at a second side of the second die. The packaged device also includes first solder bonds which each extend to a respective one of the first conductive contacts. The third die has third conductive contacts. Each of the third conductive contacts are at a third side of the third die. The third die is coupled to the first die stack via second solder bonds which each extend to a respective one of the second conductive contacts, and to a respective one of the third conductive contacts. Each die of the first die stack is coupled to each of a respective one or more other dies of the first die stack via respective hybrid bonds.

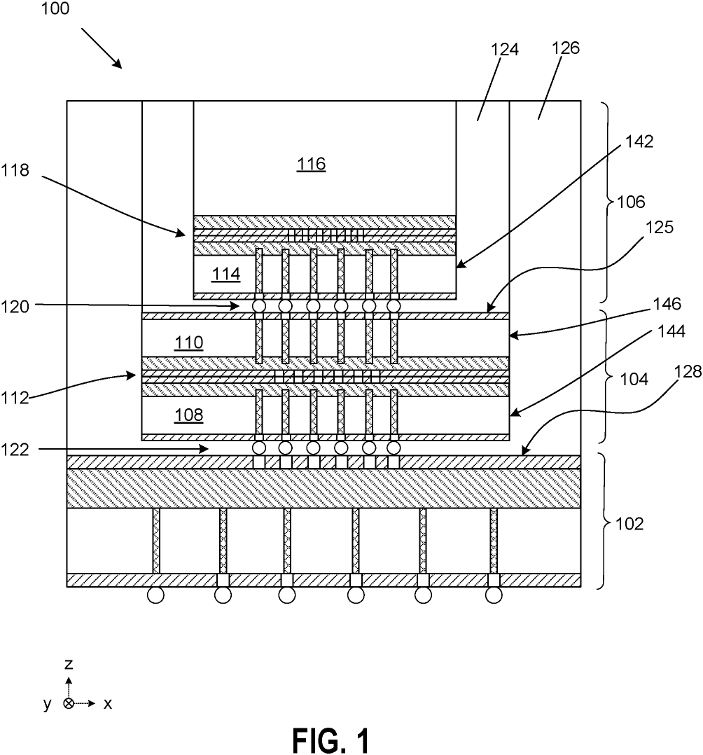

FIG. 1 is a cross-sectional view of a packaged device 100 comprising a base die (or package substrate) 102, a first die stack 104, and a second die stack 106, according to some embodiments. The first die stack 104 has a first die 108 and a second die 110 coupled to each other via hybrid bonding at an interface 112. The second die stack 106 has a third die 114 and a fourth die 116 coupled to each other via hybrid bonding at an interface 118. The first and second die stack 104, 106 are coupled to each other via solder bonding at solder bond interface 120. The first die stack 104 and the base die 102 are coupled to each other via solder bonds at solder bond interface 122. A first body 124 extends along and adjoins a sidewall structure 142 of the third die 114 of second die stack 106. A second body 126 extends along and adjoins a sidewall structure 144 of first die 108, or sidewall structure146 of second die 110, of the first die stack 106.

Base die 102 may comprise a package substrate or a base die to which any number of additional dies may be placed upon, in some embodiments. The base die 102 may comprise any integrated circuitry fabricated according to any microelectronic technology such as complementary metal oxide semiconductor (CMOS), SiGe, III-V or III-N HEMTs, etc.). The base die 102 may be any appropriate die/device, including, but not limited to, a microprocessor, a chipset, a graphics device, a wireless device, a memory device, an application specific integrated circuit, a transceiver device, an input/output device, combinations thereof, stacks thereof, or the like.

The first die, second die, third die, and fourth die 108, 110, 114, 116 may be any appropriate die/device, including, but not limited to, a microprocessor, a chipset, a graphics device, a wireless device, a memory device, an application specific integrated circuit, a transceiver device, an input/output device, combinations thereof, stacks thereof, or the like. In some embodiments, base die (package substrate or base die) 102 comprises a microprocessor and first die, second die, third die, and fourth die 108, 110, 114, 116 comprise a stack of memory devices. Packaged device 100 enables customizable die stacks for various product types, such as graphics, servers, and client computing.

In some embodiments, the first body 124 may comprise an organic mold material but may include any suitable material for fill material. In some embodiments, the first body 124 may comprise a dielectric material. In some embodiments, the first body 124 extends along and adjoins a sidewall structure 142 of the third die 114. In some embodiments, the second body 126 may comprise an organic mold material but may include any suitable material for fill material. In some embodiments, the second body 126 may comprise a dielectric material. In some embodiments, the second body 126 extends along and adjoins a sidewall structure 144, 146 of one of the first die 108 or the second die 110, respectively. The second body 126 also extends around the first body 124.

An advantage of the hybrid bonded die stacks described herein, e.g., first and second die stack 104, 106, is that the die stacks have dimensions that are similar to a single monolithic die. Accordingly, existing manufacturing processes designed for stacking single monolithic die may be used for attaching the disclosed hybrid bonded die stacks to a base die.

Another advantage of the hybrid bonded die stacks described herein, e.g., first and second die stack 104, 106, is that packaged device 100 can have about twice the number of die within the package as compared with an existing package of the same size having a stack of monolithic die. This is because the disclosed hybrid bonded die stacks have dimensions that are similar to a single monolithic die.

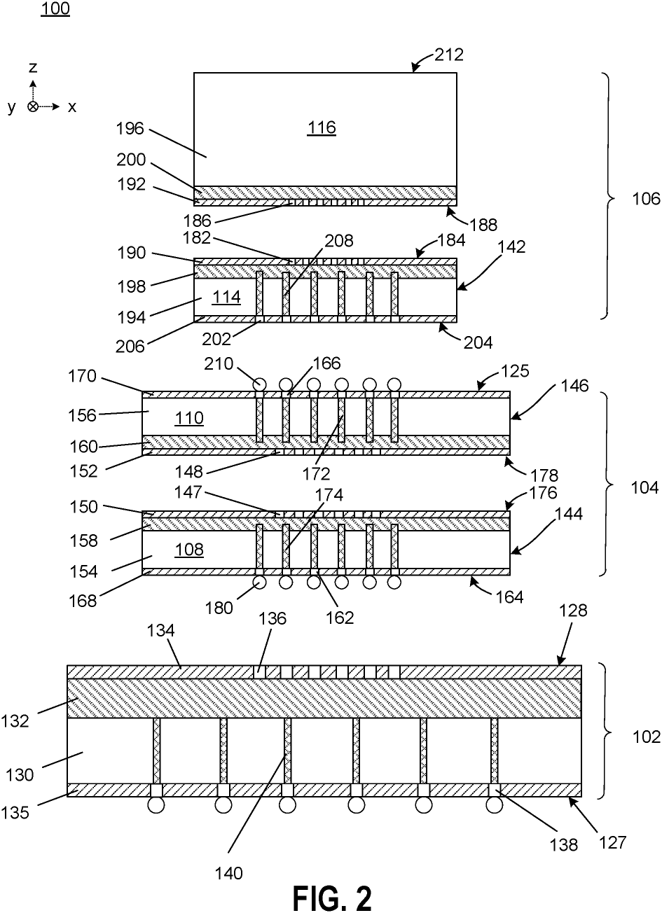

FIG. 2 is a cross-sectional, exploded view of the packaged device 100 illustrating base die 102, first die stack 104, and second die stack 106, according to some embodiments. Referring to FIG. 2, the base die 102 may have a device layer 130 and back-end-of-line (BEOL) metallization layer 132 that has been monolithically fabricated over device layer 130, wherein the metallization layer 132 may comprise circuitry structures including metal routing layers within dielectric layers. The base die 102 comprises base die dielectric material 134 between one or more base die conductive structures 136 at surface 128. The base die conductive structures 136 may be made of any appropriate conductive material, including but not limited to, metals, such as copper, silver, nickel, gold, aluminum, alloys thereof, and the like. The base die 102 may comprise conductive pads 138 on a surface 127 of the base die 102 opposite surface 128, that may be made of any appropriate conductive material, including but not limited to, metals, such as copper, silver, nickel, gold, aluminum, alloys thereof, and the like. Conductive pads 138 may be surrounded by base die dielectric material 135. The base die may comprise conductive vias 140 coupled to the conductive pads 138 and to metallization layer 132.

In an embodiment, the base die dielectric material 134, 135 may comprise silicon dioxide. The base die conductive structures 136 may comprise any appropriate conductive material, including but not limited to, metals, such as copper, silver, nickel, gold, and aluminum, alloys thereof, and the like. The base die conductive structures 136 may be formed by any known process, including but not limited to plating. Plating processes, such as electroplating and electroless plating, are well known in the art and, for purposes of clarity and conciseness, will not be discussed herein.

Referring to first die stack 104, the first die stack 104 may comprise two die, e.g., first die 108 and second die 110, or in some embodiments, first die stack 104 may comprise more than two die, each die hybrid bonded to one another in the manner described herein with respect to first die 108 and second die 110.

First die 108 may comprise first front-side die conductive structures 147 on front side 176. Second die 110 may comprise second front-side conductive structures 148 on front side 178. The first front-side die conductive structures 147 are separated by first front-side die dielectric material 150. The second front-side conductive structures 148 are separated by second front-side die dielectric material 152. First die and second die 108, 110 may comprise respective devices layers 154, 156, and respective metallization layers 158, 160. The metallization layers 158, 160 may comprise circuitry structures including metal routing layers within dielectric layers. The first die 108 may comprise conductive pads 162 at a side 164, which is the back side of first die 108. The second die 110 may comprise conductive pads 166 at the side 125, which is the back side of first die 110. Conductive pads 162, 166 may be made of any appropriate conductive material, including but not limited to, metals, such as copper, silver, nickel, gold, aluminum, alloys thereof, and the like. Conductive pads 162 may be surrounded by dielectric material 168. Conductive pads 166 may be surrounded by dielectric material 170. The first die 108 may comprise conductive vias 170 coupled to the conductive pads 162 and metallization layer 158. The second die 110 may comprise conductive vias 172 coupled to the conductive pads 166 and metallization layer 160.

As illustrated in FIG. 1, first front-side die dielectric material 150 is in direct contact with second front-side dielectric material 152 at interface 112. At interface 112, the region between the first front-side die dielectric material 150 and second front-side dielectric material 152 may comprise an insulator-insulator bonded region and may comprise a portion of a hybrid bond. In addition, at interface 112, the region between first front-side die conductive structures 147 and second front-side conductive structures 148 may comprise a metal-metal bonded region and may comprise a portion of a hybrid bond. In the hybrid bond, oxide portions are bonded together with Vander der Waals forces, while metal to metal bonds are formed by high temperature processing.

The first die stack 104 and the base die 102 are coupled to each other via solder bonds between conductive pads 162 and base die conductive structures 136 at solder bond interface 122 (See FIG. 1). The solder bonds are formed by solder balls 180. Solder balls 180 may be may have a spherical form indicative of a free-surface solder reflow. Solder balls 180 may be of any solder composition known to be suitable for electrically connecting IC dies. In some embodiments, solder balls 180 comprise a metal. In some exemplary embodiments, solder balls 180 are of a Sn--Ag--Cu (SAC) alloy.

Referring to second die stack 106, the second die stack 106 may comprise two die, e.g., third die 114 and fourth die 116, or in some embodiments, second die stack 106 may comprise more than two die, each die hybrid bonded to one another in the manner described herein with respect to third die 114 and second die 116.

Third die 114 may comprise third front-side die conductive structures 182 on front side 184. Fourth die 116 may comprise fourth front-side conductive structures 186 on front side 188, which is opposite back side 212 of fourth die 116. The third front-side die conductive structures 182 are separated by third front-side die dielectric material 190. The fourth front-side conductive structures 186 are separated by fourth front-side die dielectric material 192. Third die and fourth die 114, 116 may comprise respective devices layers 194, 196, and respective metallization layers 198, 200. The metallization layers 198, 200 may comprise circuitry structures including metal routing layers within dielectric layers. The third die 114 may comprise conductive pads 202 at a side 204, which is the back side of third die 114. Conductive pads 202 may be made of any appropriate conductive material, including but not limited to, metals, such as copper, silver, nickel, gold, aluminum, alloys thereof, and the like. Conductive pads 202 may be surrounded by dielectric material 206. The third die 114 may comprise conductive vias 208 coupled to the conductive pads 202 and metallization layer 198.

As illustrated in FIG. 1, third front-side die dielectric material 190 is in direct contact with fourth front-side dielectric material 192 at interface 118. At interface 118, the region between the third front-side die dielectric material 190 and fourth front-side dielectric material 192 may comprise an insulator-insulator bonded region and may comprise a portion of a hybrid bond. In addition, at interface 118, the region between third front-side die conductive structures 182 and fourth front-side conductive structures 186 may comprise a metal-metal bonded region and may comprise a portion of a hybrid bond. In the hybrid bond, oxide portions are bonded together with Vander der Waals forces, while metal to metal bonds are formed by high temperature processing.

The second die stack 106 and first die stack 104 are coupled to each other via solder bonds between conductive pads 202 and comprise conductive pads 166 at solder bond interface 120 (See FIG. 1). The solder bonds are formed by solder balls 210. Solder balls 210 may be may have a spherical form indicative of a free-surface solder reflow. Solder balls 210 may be of any solder composition known to be suitable for electrically connecting IC dies. In some embodiments, solder balls 210 comprise a metal. In some exemplary embodiments, solder balls 180 are of a Sn--Ag--Cu (SAC) alloy.

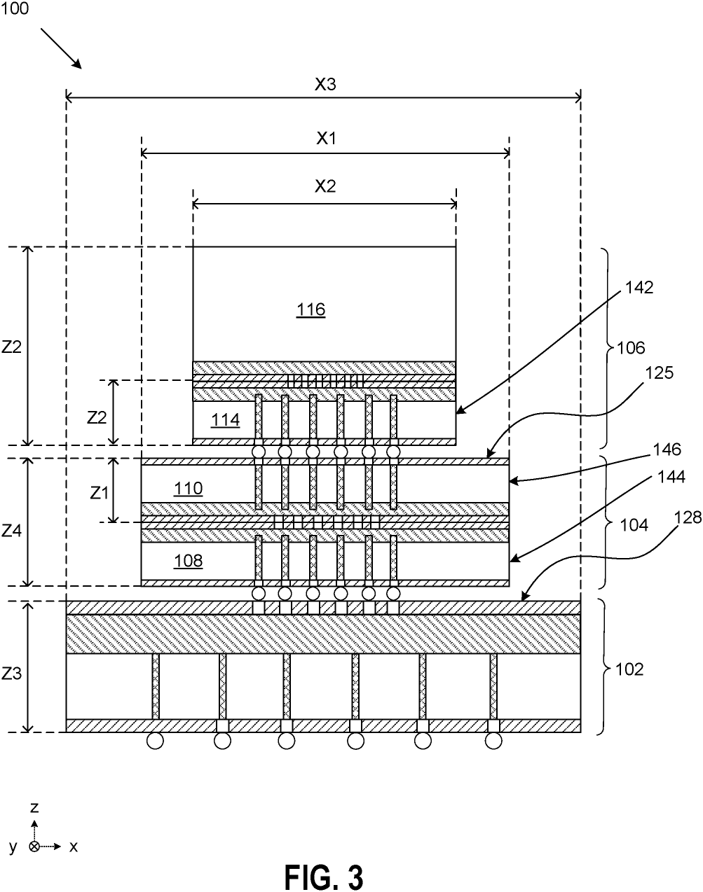

FIG. 3 is a cross-sectional view of the packaged device 100 illustrating base die 102, first die stack 104, and second die stack 106, according to some embodiments. Referring to FIG. 3, base die 102 has a height Z3 and a width X3. The first die stack 104 comprises first die 108 and second die 110. Second die 110 has a height Z3 and a width X3. The first die stack 104 has a height Z4 and a width X3. First die 108 and second die 110 may have the same height, but this not essential. The second die stack 106 comprises third die 114 and fourth die 116. Third 114 has a height Z2 and a width X2. The second die stack 106 has a height Z2 and a width X2. Third die 114 and fourth die 116 may have the same height in some embodiments, or fourth die may have a height which greater than Z2 in some embodiments.

The base die 102 has a cross-sectional profile in the x-z plane defined by distances X3 and Z3. The first die 108 has a cross-sectional profile in the x-z plane defined by distances X1 and Z5. It can be seen from FIG. 3 that the cross-sectional profile of base die 102 and the cross-sectional profile of first die 108 are each in a respective plane which is orthogonal to a plane in which the side 128 extends. In some embodiments, the cross-sectional profile of base die 102 is substantially larger than the cross-sectional profile of the first die 108. In some embodiments, the cross-sectional profile of base die 102 is substantially wider than the cross-sectional profile of the first die 108. In some embodiments, the cross-sectional profile of base die 102 is substantially the same as the cross-sectional profile of the first die 108.

The second die 110 has a first cross-sectional profile in the x-z plane defined by distances X1 and Z1. The third die 114 has a second cross-sectional profile of in the x-z plane defined by distances X2 and Z2. It can be seen from FIG. 3 that the first cross-sectional profile and the second cross-sectional profile are each in a respective plane which is orthogonal to a plane in which the second side 125 extends. In some embodiments, first cross-sectional profile of the second die 110 is substantially larger than the second cross-sectional profile of the third die 114. In some embodiments, first cross-sectional profile of the second die 110 is substantially wider than the second cross-sectional profile of the third die 114.

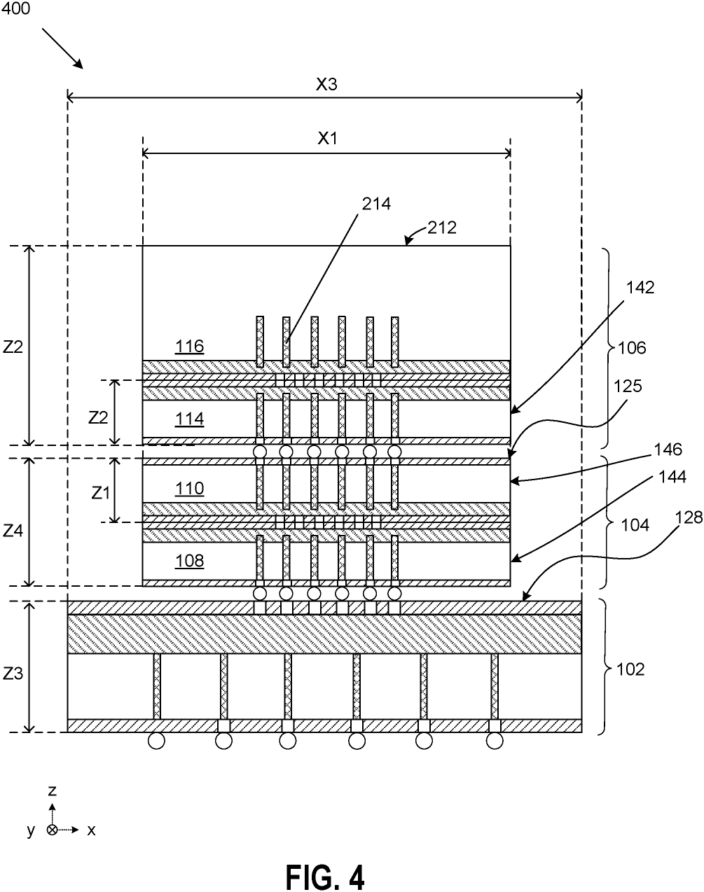

FIG. 4 is a cross-sectional view of a packaged device 400 illustrating base die 102, first die stack 104, and second die stack 106, according to some embodiments. Referring to FIG. 4, an embodiment in which the first and second die stacks 104, 106 have the same width is shown. In particular, the first die 108 or the second die 110 may have a width X1, and the third die 114 or the fourth die 116 may also have the width X1. In some embodiments, a cross-sectional profile of the second die 110 is substantially the same as a cross-sectional profile of the third die 114.

Still referring to FIG. 4, it can be seen that in some embodiments, fourth die includes conductive vias 214. In some embodiments, first and second die 108, 110 can be instances of a same die, i.e., the first and second die 108, 110 are of the same design. Similarly, third and fourth die 114, 116 can be instances of a same die, i.e., the third and fourth die 114, 116 are of the same design. In FIG. 4, it can be seen that fourth die 116 has a greater height than third die 114 because it has not been thinned, and conductive vias 214 are left hanging with connection to conductive pads at back side 212 of fourth die 116. Conductive pads are not needed because no die is to be connected to the back side of fourth die 116. Accordingly, an advantage of some embodiments is that there is no need for fourth die 116 to have a different design than third die 114.

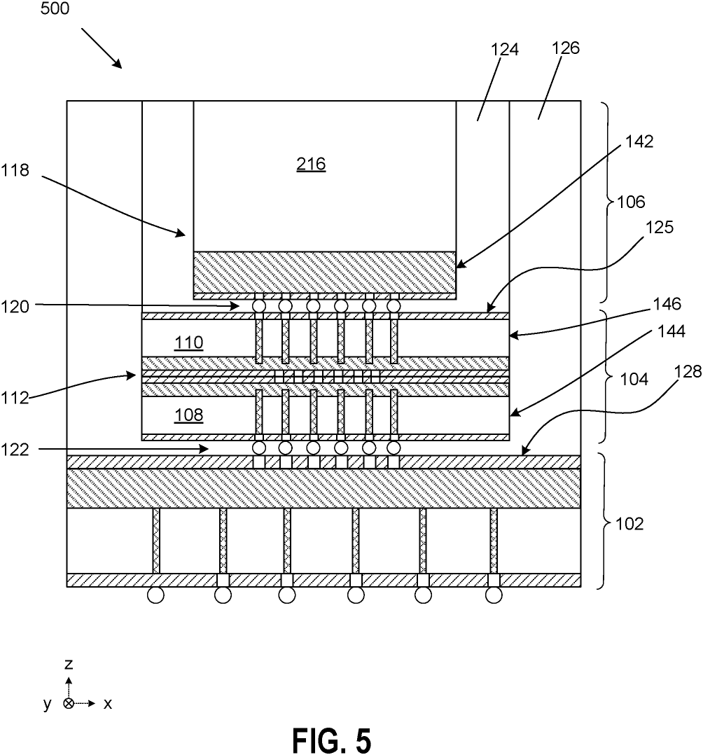

FIG. 5 is a cross-sectional view of a packaged device 500 illustrating base die 102, first die stack 104, and a monolithic die 216, according to some embodiments. According to various embodiments, a monolithic die 216 may be attached via solder bonds to the first die stack 104. As shown in FIG. 5, monolithic die 216 may be attached on top of first die stack 104. In other embodiments, monolithic die 216 may be attached below first die stack 104 via solder bonds and above base die 102 via solder bonds.

The first and second die 108, 110 of the first die stack 104, and third and fourth die, 114, 116 of the second die stack 106 of packaged device 100, as illustrated in FIGS. 1 and 2, are arranged in a front-to-front configuration. In particular, front side 176 of first die 108 is in contact with front side 178 of second die 110. In addition, front side 184 of third die 114 is in contact with front side 188 of fourth die 116. In various embodiments, die stacks may be arranged in configurations other than a front-to- front configuration.

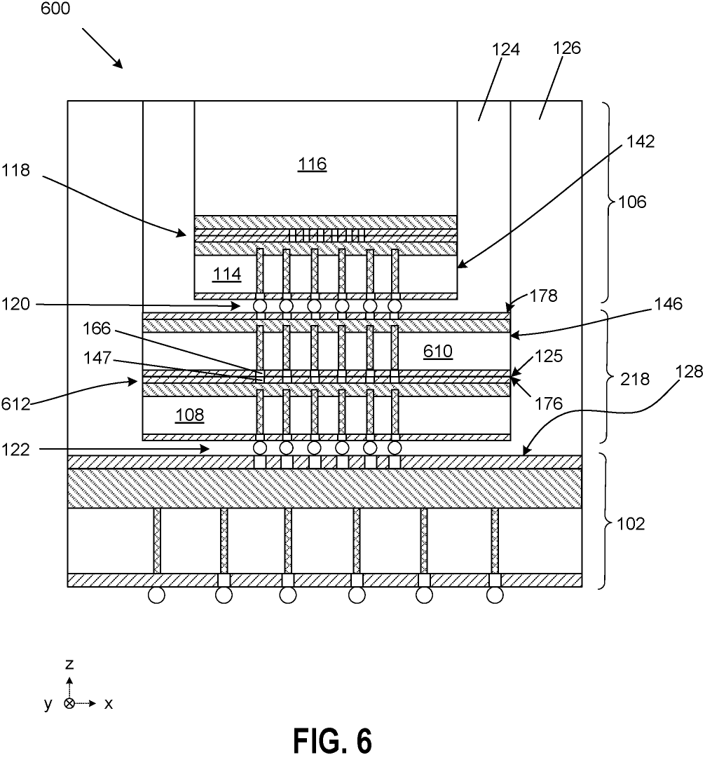

FIG. 6 is a cross-sectional view of a packaged device 600 illustrating base die 102, lower die stack 218, and upper die stack 106, according to some embodiments. Lower die stack 218 and upper die stack 106 are configured in a front-to-back configuration. Lower die stack 218 has a first die 108 and a second die 610 are coupled to each other via hybrid bonding in a front-to-back configuration at an interface 612. The second die 610 may be substantially the same as or similar to second die 110. However, second die 610 is inverted from the arrangement of second die 110 shown in FIGS. 1 and 2. Conductive pads 166 at the back side 125 of die 610 are in contact with the conductive structures 147 on front side 176 of first die 108.

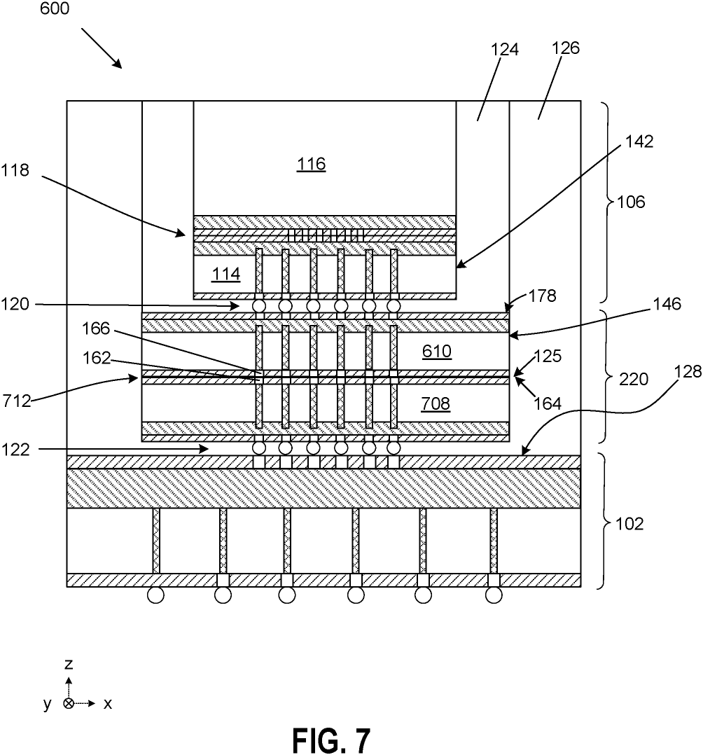

FIG. 7 is a cross-sectional view of a packaged device 700 illustrating base die 102, lower die stack 220, and upper die stack 106, according to some embodiments. Lower die stack 220 and upper die stack 106 are configured in a back-to-back configuration. Lower die stack 220 has a first die 708 and a second die 610 are coupled to each other via hybrid bonding in a back-to-back configuration at an interface 712. The first die 708 may be substantially the same as or similar to first die 108. However, first die 708 is inverted from the arrangement of first die 108 shown in FIGS. 1 and 2. Conductive pads 162 at the back side 164 of first die 610 are in contact with the conductive pads 166 at the back side 125 of die 610.

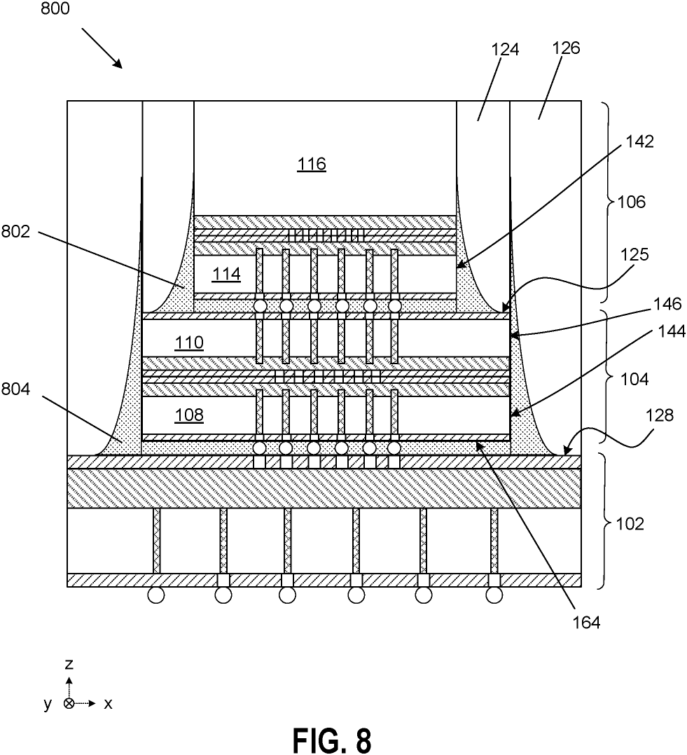

FIG. 8 is a cross-sectional view of a packaged device 800 comprising a base die 102, a first die stack 104, a second die stack 106, and underfill, according to some embodiments. The first die stack 104 has a first die 108 and a second die 110 coupled to each other via hybrid bonding. The second die stack 106 has a third die 114 and a fourth die 116 coupled to each other via hybrid bonding. The first and second die stack 104, 106 are coupled to each other via solder bonding. The first die stack 104 and the base die 102 are coupled to each other via solder bonds.

The coupling of first and second die stacks 104, 106 comprises coupling between second die 110 and third die 114. In some embodiments, coupling is between conductive pads 166 at back side 125 of second die 110 and conductive pads 202 at back side 204 of third die 114. Packaged device 800 comprises a first underfill structure 802 which extends between the second die 110 and the third die 114. Conductive pads 166 and 202 are interconnected via solder. First underfill structure 802 extends in the region between the second die 110 and the third die 114 not occupied by solder. In addition, first underfill structure 802 extends along and adjoins a sidewall structure 142 of the third die 114. First underfill structure 802 also adjoins a portion of back side 125 of second die 110 that is not in the region between the second die 110 and the third die 114, i.e., a region adjacent to the region underlying third die 114.

The coupling of first die stack 104 and the base die 102 comprises coupling between first die 108 and base die 102. In some embodiments, coupling is between conductive pads 162 at back side 164 of first die 108 and base die conductive structures 136 at surface 128 of base die 102. Packaged device 800 comprises a second underfill structure 804 which extends to the back side 164. In some embodiments, packaged device 800 comprises a second underfill structure 804 which extends between the first die 108 and the base die 102. Conductive pads 162 and base die conductive structures 136 are interconnected via solder. Second underfill structure 804 extends in the region between the first die 108 and the base die 102 not occupied by solder. In addition, second underfill structure 804 extends along and adjoins a sidewall structure 144 of the first die 108. Second underfill structure 804 also adjoins a portion of side 128 of base die 102 that is not in the region between the first die 108 and the base die 102, i.e., a region adjacent to the region underlying first die 108.

As shown in FIG. 8, the first body 124 extends along and adjoins a sidewall structure 142 of the third die 114 of second die stack 106. In regions where first underfill structure 802 sidewall structure 142 of the third die 114, first body 124 extends along and adjoins the first underfill structure 802. In addition, in the absence of second underfill structure 804, a second body 126 extends along and adjoins a sidewall structure 144 of first die 108, or sidewall structure 146 of second die 110. In the presence of second underfill structure 804, the second body 126 extends along and adjoins second underfill structure 804 in regions where it would otherwise adjoin sidewall structure 114 or 146.

In some embodiments, the first and second underfill structures 802, 804 may comprise materials comprising organic polymers and inorganic fillers. The first and second underfill structures 802, 804 may comprise an epoxy material. The material used for first and second underfill structures 802, 804 may be selected based on structural strength and thermal expansion properties. First and second underfill structures 802, 804 may be formed using a capillary underfill process.

While the die stacks in packaged devices have been described herein as having two dies per die stack and a single package substrate or a base die, e.g., FIG. 1 shows a single package substrate or a base die and two die stacks, each having two dies, it should be appreciated that in other embodiments, more than two dies can be included in a die stack. For example, four, six, or eight dies can be included in a die stack in some embodiments. In addition, while packaged devices have been described herein as having two die stacks on a base die or substrate, it should be appreciated that in other embodiments, a packaged device can have more than two die stacks on a package substrate or a base die, e.g., one, three, four, five, or six die stacks.

The package devices described herein may be assembled and/or fabricated with one or more of the features or attributes provided in accordance with various embodiments. A number of different assembly and/or fabrication methods may be practiced to generate a package device having one or more of the features or attributes described herein.

Package devices described herein may be assembled from “known good” hybrid bonded die cubes or stacks. For example, in various embodiments, first die, second die, third die, and fourth die 108, 110, 114, 116 may be tested prior to being assembled into respective first and second die stacks 104, 106. In addition, first and second die stacks 104, 106 may be tested before being attached to each other or to base die 102. Further, base die 102 may be tested prior to being attached to a die stack.

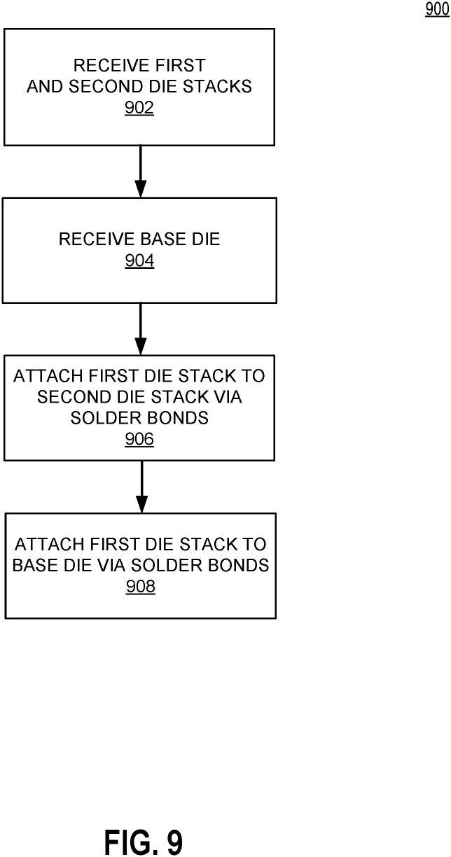

FIG. 9 illustrates a flow diagram of methods 900 for assembling a packaged device according to some embodiments. At 902, first and second die stacks 104, 106 are received. In some embodiments, first die, second die, third die, and fourth die 108, 110, 114, 116 are received and the first and second die stacks 104, 106 are fabricated. Specifically, first die and second die 108, 110 are physically attached and electrically coupled via hybrid bonding to form first die stack 104. Third and fourth die are physically attached and electrically coupled attached via hybrid bonding to form second side stack 106.

At 904, a base die 102 is received. In some embodiments, base die 102 may be fabricated. In some embodiments, a package substrate may be received or fabricated instead of a base die. At 906, first and second die stacks 104, 106 are physically attached and electrically coupled to one another via solder bonds. At 908, first stack and base die 102 are physically attached and electrically coupled to one another via solder bonds.

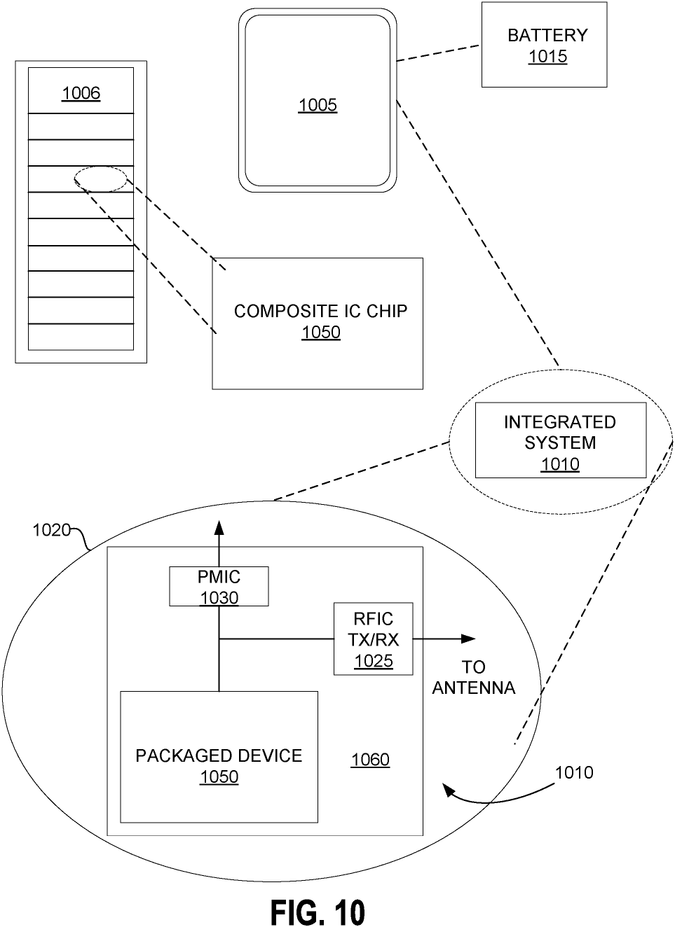

FIG. 10 illustrates a mobile computing platform 1005 and a data server machine 1006 employing a packaged device having a first die stack having first die and second die coupled to each other via hybrid bonding, and third die coupled to the first die stack via solder bonding, for example as described elsewhere herein. Server machine 1006 may be any commercial server, for example including any number of high-performance computing platforms disposed within a rack and networked together for electronic data processing, which in the exemplary embodiment includes a packaged device having a first die stack having a first die and a second die coupled to each other via hybrid bonding, and a third die coupled to the first die stack via solder bonding, for example as described elsewhere herein. The mobile computing platform 1005 may be any portable device configured for each of electronic data display, electronic data processing, wireless electronic data transmission, or the like. For example, the mobile computing platform 1005 may be any of a tablet, a smart phone, laptop computer, etc., and may include a display screen (e.g., a capacitive, inductive, resistive, or optical touchscreen), an integrated system 1010, and a battery 1015.

As illustrated in the expanded view 1020, the packaged device 1050 having a first die stack having a first die and a second die coupled to each other via hybrid bonding, and a third die coupled to the first die stack via solder bonding includes a base die comprising a microprocessor and a stack of memory devices, wherein the memory devices comprise first die and second die 108, 110 coupled via hybrid bonding, and third die and fourth die 114, 116 coupled via hybrid bonding. The packaged device 1050 is further coupled PMIC (power management IC) 1030 and an RF (wireless) integrated circuit (RFIC) 1025 including a wideband RF (wireless) transmitter and/or receiver. PMIC 1030 may perform battery power regulation, DC-to-DC conversion, etc., and so has an input coupled to battery 1015 and with an output providing a current supply to other functional modules. As further illustrated, in the exemplary embodiment, RFIC 1025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

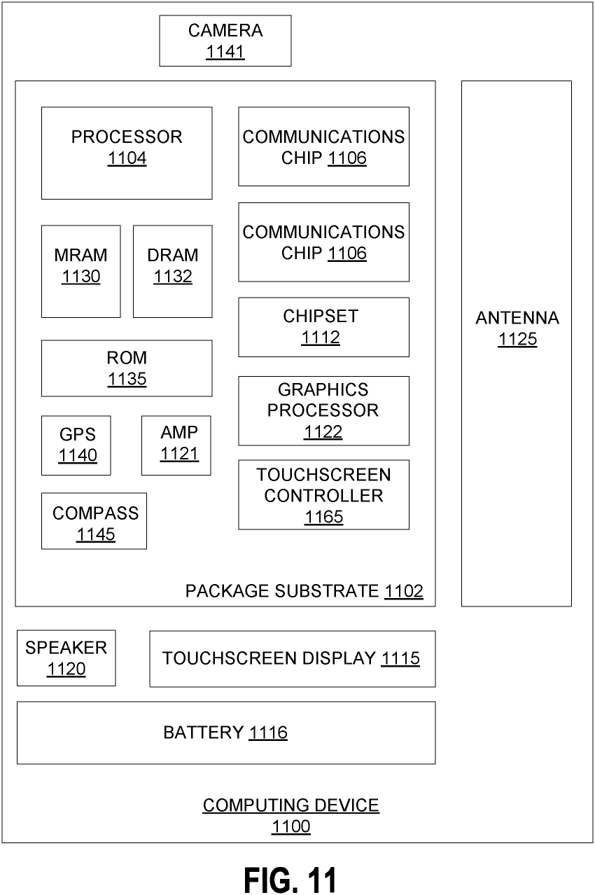

FIG. 11 is a functional block diagram of an electronic computing device 1100, in accordance with an embodiment of the present invention. Computing device 1100 may be found inside either mobile computing platform 1005 or server machine 1006, for example. Device 1100 further includes a package substrate 1102 hosting a number of components, such as, but not limited to, a processor 1104 (e.g., an applications processor). Processor 1104 may be physically and/or electrically coupled to package substrate 1102. In some examples, processor 1104 is within a packaged device having a first die stack having a first die and a second die coupled to each other via hybrid bonding, and a third die coupled to the first die stack via solder bonding, for example as described elsewhere herein. Processor 1104 may be implemented with circuitry in any or all of the IC die of the composite IC die package. In general, the term “processor” or “microprocessor” may refer to any device or portion of a device that processes electronic data from registers and/or memory to transform that electronic data into other electronic data that may be further stored in registers and/or memory.

In various examples, one or more communication chips 1106 may also be physically and/or electrically coupled to the package substrate 1102. In further implementations, communication chips 1106 may be part of processor 1104. Depending on its applications, computing device 1100 may include other components that may or may not be physically and electrically coupled to package substrate 1102. These other components include, but are not limited to, volatile memory (e.g., DRAM 1132), non-volatile memory (e.g., ROM 1135), flash memory (e.g., NAND or NOR), magnetic memory (MRAM 1130), a graphics processor 1122, a digital signal processor, a crypto processor, a chipset 1112, an antenna 1125, touchscreen display 1115, touchscreen controller 1165, battery 1116, audio codec, video codec, power amplifier 1121, global positioning system (GPS) device 1140, compass 1145, accelerometer, gyroscope, speaker 1120, camera 1141, and mass storage device (such as hard disk drive, solid-state drive (SSD), compact disk (CD), digital versatile disk (DVD), and so forth), or the like. In some exemplary embodiments, at least two of the functional blocks noted above are within a composite IC die package structure including a IC die bonded to two sides of an interposer, for example as described elsewhere herein. For example, processor 1104 be implemented with circuitry in an IC die on a first side of the interposer, and an electronic memory (e.g., MRAM 1130 or DRAM 1132) may be implemented with circuitry in an IC die on a second side of the interposer.

Communication chips 1106 may enable wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1106 may implement any of a number of wireless standards or protocols. As discussed, computing device 1100 may include a plurality of communication chips 1106. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following examples pertain to further embodiments. Specifics in the examples may be used anywhere in one or more embodiments. All optional features of the apparatus described herein may also be implemented with respect to a method or process. The examples can be combined in any combinations. For example, example 4 can be combined with example 2.

Example 1: A packaged device comprising: a first die stack comprising: a first die comprising first conductive contacts each at a first side of the first die; and a second die comprising second conductive contacts each at a second side of the second die; first solder bonds which each extend to a respective one of the first conductive contacts; a third die comprising third conductive contacts each at a third side of the third die, wherein the third die is coupled to the first die stack via second solder bonds which each extend to a respective one of the second conductive contacts, and to a respective one of the third conductive contacts; wherein each die of the first die stack is coupled to each of a respective one or more other dies of the first die stack via respective hybrid bonds.

Example 2: The packaged device of example 1, wherein the packaged device comprises a second die stack coupled to the first die stack, the second die stack comprising the third die; and wherein each die of the second die stack is coupled to each of a respective one or more other dies of the second die stack via respective hybrid bonds.

Example 3: The packaged device of example 2, wherein a first cross-sectional profile of the second die is substantially larger than a second cross-sectional profile of the third die; and wherein the first cross-sectional profile and the second cross-sectional profile are each in a respective plane which is parallel to a plane in which the second side extends.

Example 4: The packaged device of example 1, further comprising: a first body of a first mold compound, wherein the first body extends along and adjoins a sidewall structure of the third die; and a second body of a second mold compound, wherein the second body extends along and adjoins a sidewall structure of one of the first die or the second die, wherein the second body extends around the first body.

Example 5: The packaged device of example 4, further comprising: a first underfill structure which extends between the second die and the third die; and a second underfill structure which extends to the first side.

Example 6: The packaged device of example 1, wherein a first cross-sectional profile of the second die is substantially larger than a second cross-sectional profile of the third die; and wherein the first cross-sectional profile and the second cross-sectional profile are each in a respective plane which is parallel to a plane in which the second side extends.

Example 7: The packaged device of example 1, wherein the third die is a top die of a second die stack comprising the first die stack.

Example 8: The packaged device of example 1, wherein each die of the first die stack is bonded in a respective front-to-back configuration to another die of the first die stack.

Example 9: The packaged device of example 1, wherein each die of the first die stack is bonded to another die of the first die stack in a respective one of a front-to-front configuration, or a back-to-back configuration.

Example 10: The packaged device of example 1, further comprising a package substrate coupled to the first die stack via the first solder bonds.

Example 11:The packaged device of example 1, further comprising a fourth die coupled to the first die stack via the first solder bonds.

Example 12: A packaged device comprising: a first die stack comprising: a first die comprising first conductive contacts each at a first side of the first die; and a second die comprising second conductive contacts each at a second side of the second die, wherein each die of the first die stack is coupled to each of a respective one or more other dies of the first die stack via respective hybrid bonds; first solder bonds which each extend to a respective one of the first conductive contacts; a third die comprising third conductive contacts each at a third side of the third die, wherein the third die is coupled to the first die stack via second solder bonds which each extend to a respective one of the second conductive contacts, and to a respective one of the third conductive contacts; and a package substrate coupled to the first die stack via the first solder bonds.

Example 13: The packaged device of example 12, wherein the packaged device comprises a second die stack coupled to the first die stack, the second die stack comprising the third die; and wherein each die of the second die stack is coupled to each of a respective one or more other dies of the second die stack via respective hybrid bonds.

Example 14: The packaged device of example 13, wherein a first cross-sectional profile of the second die is substantially larger than a second cross-sectional profile of the third die; and wherein the first cross-sectional profile and the second cross-sectional profile are each in a respective plane which is parallel to a plane in which the second side extends.

Example 15: A system comprising: a power supply; a packaged device coupled to the power supply, comprising: a first die stack comprising: a first die comprising first conductive contacts each at a first side of the first die; and a second die comprising second conductive contacts each at a second side of the second die; first solder bonds which each extend to a respective one of the first conductive contacts; a third die comprising third conductive contacts each at a third side of the third die, wherein the third die is coupled to the first die stack via second solder bonds which each extend to a respective one of the second conductive contacts, and to a respective one of the third conductive contacts; wherein each die of the first die stack is coupled to each of a respective one or more other dies of the first die stack via respective hybrid bonds.

Example 16: The system of example 15, wherein the packaged device comprises a second die stack coupled to the first die stack, the second die stack comprising the third die; and wherein each die of the second die stack is coupled to each of a respective one or more other dies of the second die stack via respective hybrid bonds.

Example 17: The system of example 15, further comprising: a first body of a first mold compound, wherein the first body extends along and adjoins a sidewall structure of the third die; and a second body of a second mold compound, wherein the second body extends along and adjoins a sidewall structure of one of the first die or the second die, wherein the second body extends around the first body.

Example 18: The system of example 15, further comprising: a first underfill structure which extends between the second die and the third die; and a second underfill structure which extends to the first side.

Example 19: The system of example 15, wherein a first cross-sectional profile of the second die is substantially larger than a second cross-sectional profile of the third die; and wherein the first cross-sectional profile and the second cross-sectional profile are each in a respective plane which is parallel to a plane in which the second side extends.

Example 20: The system of example 15, further comprising a fourth die coupled to the first die stack via the first solder bonds.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. A packaged device comprising:
a first die stack comprising:
a first die comprising first conductive contacts at a first side of the first die; and
a second die comprising second conductive contacts at a second side of the second die, wherein the first die is coupled to the second die through a hybrid bond;
first solder bonds coupled with the first conductive contacts; and
a third die comprising third conductive contacts coupled to the second conductive contacts by second solder bonds.

2. The packaged device of claim 1, wherein the packaged device comprises a second die stack coupled to the first die stack, the second die stack comprising the third die; and
wherein each die of the second die stack is coupled to each of a respective one or more other dies of the second die stack via respective hybrid bonds.

3. The packaged device of claim 2, wherein a first cross-sectional profile of the second die is substantially larger than a second cross-sectional profile of the third die; and
wherein the first cross-sectional profile and the second cross-sectional profile are each in a respective plane which is parallel to a plane in which the second side extends.

4. The packaged device of claim 1, further comprising:
a first body of a first mold compound, wherein the first body extends along and adjoins a sidewall structure of the third die; and
a second body of a second mold compound, wherein the second body extends along and adjoins a sidewall structure of one of the first die or the second die, wherein the second body extends around the first body.

5. The packaged device of claim 4, further comprising:
a first underfill structure which extends between the second die and the third die; and
a second underfill structure which extends to the first side.

6. The packaged device of claim 1, wherein a first cross-sectional profile of the second die is substantially larger than a second cross-sectional profile of the third die; and
wherein the first cross-sectional profile and the second cross-sectional profile are each in a respective plane which is parallel to a plane in which the second side extends.

7. The packaged device of claim 1, wherein the third die is a top die of a second die stack comprising the first die stack.

8. The packaged device of claim 1, wherein each die of the first die stack is bonded in a respective front-to-back configuration to another die of the first die stack.

9. The packaged device of claim 1, wherein each die of the first die stack is bonded to another die of the first die stack in a respective one of a front-to-front configuration, or a back-to-back configuration.

10. The packaged device of claim 1, further comprising a package substrate coupled to the first die stack via the first solder bonds.

11. The packaged device of claim 1, further comprising a fourth die coupled to the first die stack via the first solder bonds.

12. A packaged device comprising:
a first die stack comprising:
a first die comprising first conductive contacts at a first side of the first die; and
a second die comprising second conductive contacts at a second side of the second die, wherein the first die is coupled to the second die through a hybrid bond;
first solder bonds coupled with the first conductive contacts; and
a third die comprising third conductive contacts coupled to the second conductive contacts by second solder bonds; and
a package substrate coupled to the first die stack via the first solder bonds.

13. The packaged device of claim 12, wherein the packaged device comprises a second die stack coupled to the first die stack, the second die stack comprising the third die; and
wherein each die of the second die stack is coupled to each of a respective one or more other dies of the second die stack via respective hybrid bonds.

14. The packaged device of claim 13, wherein a first cross-sectional profile of the second die is substantially larger than a second cross-sectional profile of the third die; and
wherein the first cross-sectional profile and the second cross-sectional profile are each in a respective plane which is parallel to a plane in which the second side extends.

15. A system comprising:
a power supply;
a packaged device coupled to the power supply, comprising:
a first die stack comprising:
a first die comprising first conductive contacts at a first side of the first die; and
a second die comprising second conductive contacts at a second side of the second die, wherein the first die is coupled to the second die through a hybrid bond;
first solder bonds coupled with the first conductive contacts; and
a third die comprising third conductive contacts coupled to the second conductive contacts by second solder bonds.

16. The system of claim 15, wherein the packaged device comprises a second die stack coupled to the first die stack, the second die stack comprising the third die; and
wherein each die of the second die stack is coupled to each of a respective one or more other dies of the second die stack via respective hybrid bonds.

17. The system of claim 15, further comprising:
a first body of a first mold compound, wherein the first body extends along and adjoins a sidewall structure of the third die; and
a second body of a second mold compound, wherein the second body extends along and adjoins a sidewall structure of one of the first die or the second die, wherein the second body extends around the first body.

18. The system of claim 15, further comprising:
a first underfill structure which extends between the second die and the third die; and
a second underfill structure which extends to the first side.

19. The system of claim 15, wherein a first cross-sectional profile of the second die is substantially larger than a second cross-sectional profile of the third die; and
wherein the first cross-sectional profile and the second cross-sectional profile are each in a respective plane which is parallel to a plane in which the second side extends.

20. The system of claim 15, further comprising a fourth die coupled to the first die stack via the first solder bonds.
